(19) United States
(12) Patent Application Publication
(10) Pub. No.: US 2019/0334005 A1
(43) Pub. Date: Oct. 31, 2019

(54) DISPLAY PANEL AND MANUFACTURING METHOD THEREFOR

(71) Applicant: HKC Corporation Limited, Shenzhen City, Guangdong (CN)

(72) Inventor: Beizhou HUANG, Shenzhen City, Guangdong (CN)

(21) Appl. No.: 16/462,064

(22) PCT Filed: Dec. 20, 2017
(86) PCT No.: PCT/CN2017/117339

§ 371 Date: May 17, 2019

(30) Foreign Application Priority Data
Oct. 12, 2017 (CN) 201710948846.1

(51) Int. Cl. H01L 29/423; H01L 21/311; H01L 27/12; H01L 29/51; H01L 29/40; H01L 21/027; H01L 29/49

(52) U.S. Cl. CPC H01L 29/42384; H01L 21/31144; H01L 29/42368; H01L 27/1288; H01L 2029/42388; H01L 29/401; H01L 21/0274; H01L 29/4908; H01L 29/513

(57) ABSTRACT

This application provides a display panel and a manufacturing method therefor. The method for manufacturing a display panel includes: providing a substrate; forming a gate layer on the substrate; forming a gate insulation layer on the substrate and covering the gate layer by the gate insulation layer, where the gate insulation layer has a first thickness; etching, by using a photomask, the gate insulation layer on the gate layer, and making the gate insulation layer on the gate layer have a second thickness, where the gate insulation layer has an outer surface; forming a semiconductor layer on the gate insulation layer; and forming a source layer and a drain layer on the semiconductor layer, and uncovering a part of the semiconductor layer, where the first thickness of the gate insulation layer is greater than the second thickness of the gate insulation layer.

### BACKGROUND

### Technical Field

This application relates to the display field, and in particular, to a display panel and a manufacturing method therefor.

### Related Art

Flat display apparatuses, with many advantages such as wide color gamut and power saving, are widely applied to various fields. Existing flat display apparatuses mainly include liquid crystal displays (LCD), organic light emitting diode (OLED) display apparatuses and quantum dot light emitting diode (QLED) display apparatuses. A thin film transistor (TFT) can be formed on a glass substrate or a plastic substrate and is usually used as an active switch, thereby being an important part of a flat display apparatus. With development, more and higher requirements such as having an antistatic property are imposed on display panels and display apparatuses. Some products, due to a high sensitivity, have an especially high requirement on antistatic properties of elements such as the active switch.

During TFT production and manufacturing, a plurality of film layers having different functions is plated on an array substrate, and different film layers are formed in different mechanical devices and reaction chambers. During film plating and substrate carrying, it is hard to avoid generation of a large quantity of electrostatic charges. The electrostatic charges accumulate on the array substrate. When the array substrate is in contact with a transmission device, a relatively large electric potential difference is caused. This breaks down a film layer near a contact point, thus significantly affecting quality of a flat display panel or a flat display apparatus.

### SUMMARY

To resolve the foregoing technical problem, an objective of this application is to provide a display panel and a manufacturing method therefor. According to this application, a thickness of a gate insulation layer of an active switch is selectively increased, while a thickness of the gate insulation layer on a gate layer remains unchanged. In this way, an antistatic capability of the active switch can be improved without affecting properties such as an electrical property of the active switch.

The objective of this application is achieved and the technical problem of this application is resolved by using the following technical solutions. A manufacturing method for a display panel provided in this application comprises: providing a substrate; forming a gate layer on the substrate; forming a gate insulation layer on the substrate and covering the gate layer by the gate insulation layer, where the gate insulation layer has a first thickness; etching, by using a photomask, the gate insulation layer on the gate layer, and making the gate insulation layer on the gate layer have a second thickness, where the gate insulation layer has an outer surface; forming a semiconductor layer on the gate insulation layer; and forming a source layer and a drain layer on the semiconductor layer, and uncovering a part of the semiconductor layer, where the first thickness of the gate insulation layer is greater than the second thickness of the gate insulation layer.

In an embodiment of this application, the first thickness of the gate insulation layer is in a range of 6000 Å to 10000 Å. The first thickness of the gate insulation layer is 6000 Å.

In an embodiment of this application, the second thickness of the gate insulation layer is in a range of 500 Å to 5500 Å. The second thickness of the gate insulation layer is 4000 Å.

In an embodiment of this application, the outer surface of the etched gate insulation layer is a flat surface.

In an embodiment of this application, the photomask is a half-tone photomask or a gray-tone photomask.

In an embodiment of this application, the method for manufacturing a display panel further comprises: forming a passivation layer on the substrate, where the passivation layer covers the source layer, the drain layer, and the semiconductor layer.

In an embodiment of this application, the semiconductor layer is a polycrystalline silicon layer, an amorphous silicon layer, or an oxide semiconductor layer.

Further, the objective of this application may be achieved and the technical problem of this application may be resolved by using the following technical solutions.

Another objective of this application is to provide a display panel. The display panel comprises: a substrate; a gate layer, disposed on the substrate; a gate insulation layer, disposed on the substrate and covering the gate layer, where a part of the gate insulation layer on the gate layer has a second thickness, an other part of the gate insulation layer locating on the substrate has a first thickness, and the gate insulation layer has an outer surface; a semiconductor layer, disposed on the gate insulation layer; a source layer and a drain layer, disposed on the semiconductor layer and uncovering a part of the semiconductor layer; and a passivation layer, disposed on the substrate, where the passivation layer covers the source layer, the drain layer, and the semiconductor layer, where the first thickness of the gate insulation layer is greater than the second thickness of the gate insulation layer, and the outer surface of the gate insulation layer is a flat surface.

In an embodiment of this application, the first thickness of the gate insulation layer is in a range of 6000 Å to 10000 Å. The first thickness of the gate insulation layer is 6000 Å.

In an embodiment of this application, the second thickness of the gate insulation layer is in a range of 500 Å to 5500 Å. The second thickness of the gate insulation layer is 4000 Å.

In an embodiment of this application, the gate insulation layer is a single-layer gate insulation layer.

In an embodiment of this application, the gate insulation layer comprises a first gate insulation layer and a second gate insulation layer superposing together.

In an embodiment of this application, the first gate insulation layer and the gate layer have same heights, and the second gate insulation layer is disposed on the gate layer and the first gate insulation layer.

Still another objective of this application is to provide A manufacturing method for a display panel. The method for manufacturing a display panel comprises: providing a substrate; forming a gate layer on the substrate; forming a gate insulation layer on the substrate and covering the gate layer by the gate insulation layer, where the gate insulation layer has a first thickness; etching, by using a photomask, the gate insulation layer on the gate layer, and making the gate insulation layer on the gate layer have a second thickness, where the gate insulation layer has an outer surface; forming a semiconductor layer on the gate insulation layer; forming a source layer and a drain layer on the semiconductor layer, and uncovering a part of the semiconductor layer; and forming a passivation layer on the substrate, where the passivation layer covers the source layer, the drain layer, and the semiconductor layer; the photomask is a half-tone photomask or a gray-tone photomask, the semiconductor layer is a polycrystalline silicon layer, an amorphous silicon layer, or an oxide semiconductor layer.

According to this application, a thickness of a gate insulation layer of an active switch is selectively increased, while a thickness of the gate insulation layer on a gate layer remains unchanged. In this way, an antistatic capability of the active switch can be improved without affecting properties such as an electrical property of the active switch.

### BRIEF DESCRIPTION OF THE DRAWINGS

FIG. 1 is a schematic diagram of an exemplary display panel;

FIG. 2a is a schematic diagram of a manufacturing process of a display panel according to an embodiment of this application;

FIG. 2b is a schematic diagram of a manufacturing process of a display panel according to an embodiment of this application;

FIG. 3 is a schematic diagram of a manufacturing step of a display panel according to an embodiment of this application; and

FIG. 4 is a schematic diagram of a display panel according to an embodiment of this application.

### DETAILED DESCRIPTION

The following embodiments are described with reference to the accompanying drawings, which are used to exemplify specific embodiments for implementation of this application. Terms about directions mentioned in this application, such as “on”, “below”, “front”, “back”, “left”, “right”, “in”, “out”, and “side surface” merely refer to directions in the accompanying drawings. Therefore, the terms used about directions are used to describe and understand this application, and are not intended to limit this application.

The accompanying drawings and the description are considered to be essentially exemplary, rather than limitative. In the figures, modules with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a base is described to be “on” “another component”, the component may be directly on the another component, or there may be an intermediate component.

In addition, throughout this specification, unless otherwise explicitly described to have an opposite meaning, the word “include” is understood as including the component, but not excluding any other component. In addition, throughout the specification, “on” means that one is located above or below a target component and does not necessarily mean that one is on the top based on a gravity direction.

To further describe the technical measures taken in this application to achieve the intended application objective and effects thereof, specific implementations, structures, features, and effects of a display panel and a manufacturing method therefor that are provided according to this application are described below in detail with reference to the drawings and specific embodiments.

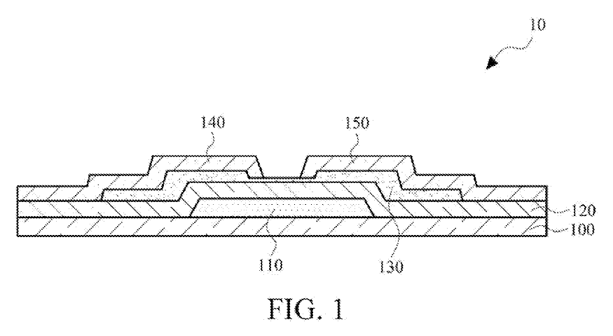

FIG. 1 is a schematic diagram of an exemplary display panel. Referring to FIG. 1, the exemplary display panel 10 includes a substrate 100 and a plurality of active switches. Each active switch includes: a gate layer 110, disposed on the substrate 100; a gate insulation layer 120, disposed on the substrate 100 and covering the gate layer 110; a semiconductor layer 130, disposed on the gate insulation layer 120; and a source layer 140 and a drain layer 150, disposed opposite to each other on the semiconductor layer 130 and uncovering a part of the semiconductor layer 130. According to the designed active switch, a thickness of the gate insulation layer 120 between the substrate 100 and the source layer 140 and the drain layer 150 is in a range of 1000 Å to 10000 Å (where A is a unit of length, and 1 Å=1.0*10⁻¹⁰ m), and the thickness of the gate insulation layer 120 ensuring properties of the active switch is approximately 4000 Å. When an electric potential difference between two ends of the active switch is relatively large, the gate insulation layer 120 is easily broken down, causing loss of properties of the active switch and unrecoverable flaws of the substrate and the display panel. If the thickness of the gate insulation layer 120 is increased, for example, increased to 10000 Å to prevent harm brought by static electricity, properties of the active switch may be affected.

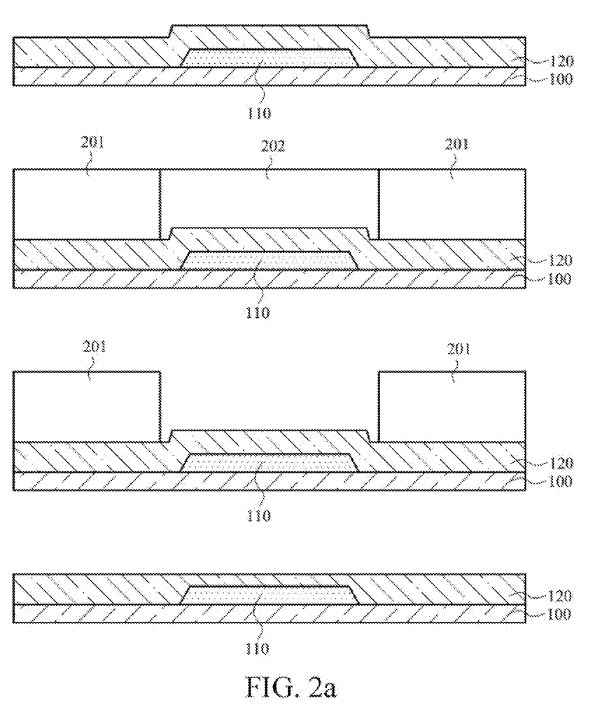

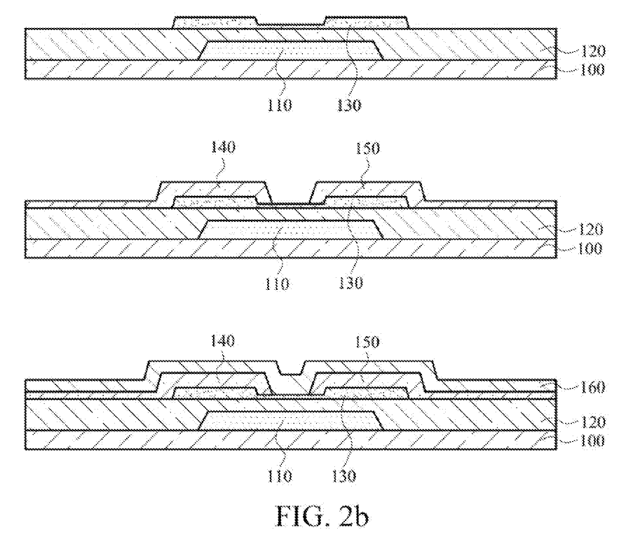

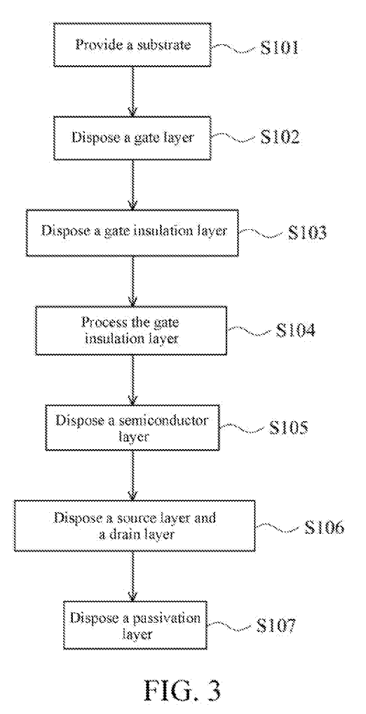

FIG. 2a and FIG. 2b are each a schematic diagram of a manufacturing process of a display panel according to an embodiment of this application and FIG. 3 is a schematic diagram of a manufacturing step of a display panel according to an embodiment of this application. Referring to FIG. 2a, FIG. 2b, and FIG. 3, in an embodiment of this application, A manufacturing method for a display panel includes the following steps:

Step S101: Provide a substrate. A substrate 100 is provided.

Step S102: Dispose a gate layer. A gate layer 110 is disposed on the substrate 100.

Step S103: Dispose a gate insulation layer. A gate insulation layer 120 is disposed on the substrate 100 and the gate layer 110 is covered by using the gate insulation layer 120, where the gate insulation layer 120 has a first thickness.

Step S104: Process the gate insulation layer. Photoresist (not shown) is coated on the gate insulation layer 120. Exposure is performed by using a photomask. The photomask divides the gate insulation layer 120 into a non-exposed area 201 and an exposed area 202, and the exposed area 202 is on the gate layer 110. Developing is performed on the exposed substrate 100 and photoresist on the non-exposed area 201 is kept. Incomplete etching is performed on the gate insulation layer 120 (that is, the gate insulation layer 120 corresponding to the exposed area 202) not covered by photoresist, the gate insulation layer 120 on the gate layer 110 is made to have a second thickness, and the gate insulation layer 120 has an outer surface.

Step S105: Dispose a semiconductor layer. A semiconductor layer 130 is disposed on the gate insulation layer 120, where the semiconductor layer 130 is on and covers the gate layer 110.

Step S106: Dispose a source layer and a drain layer. A source layer 140 and a drain layer 150 are disposed on the semiconductor layer 130 and uncover a part of the semiconductor layer 130, where the uncovered semiconductor layer 130 is on the gate layer 110.

Step S107: Dispose a passivation layer. A passivation layer 160 is disposed on the substrate 100 and covers the source layer 140, the drain layer 150, and the semiconductor layer 130.

In an embodiment of this application, the first thickness of the gate insulation layer 120 is greater than the second thickness of the gate insulation layer 120. The second thickness of the incompletely etched gate insulation layer 120 is the same as or similar to the thickness of the gate insulation layer 120 in the exemplary display panel 10.

In an embodiment of this application, the first thickness of the gate insulation layer 120 is in a range of 6000 Å to 10000 Å, and the second thickness of the gate insulation layer 120 is in a range of 500 Å to 5500 Å. The first thickness and the second thickness of the gate insulation layer 120 may be regulated according to different types and requirements of the display panel. Specifically, the first thickness of the gate insulation layer 120 may be, for example, in a range of 6000 Å to 7000 Å (and is preferably 6000 Å or 6500 Å), or in a range of 6500 Å to 7200 Å (and is preferably 6800 Å). Correspondingly, the second thickness of the gate insulation layer 120 may be, for example, in a range of 3800 Å to 4200 Å (and is preferably 4000 Å), or in a range of 3500 Å to 4500 Å (and is preferably 4000 Å).

In an embodiment of this application, the semiconductor layer 130 is a polycrystalline silicon layer, an amorphous silicon layer, or an oxide semiconductor layer.

In an embodiment of this application, the photomask may be, for example, a half-tone photomask or a gray-tone photomask.

In an embodiment of this application, the outer surface of the gate insulation layer 120 on which the processing by using the photomask and the etching processing are performed is a flat surface. This facilitates a subsequent manufacturing process.

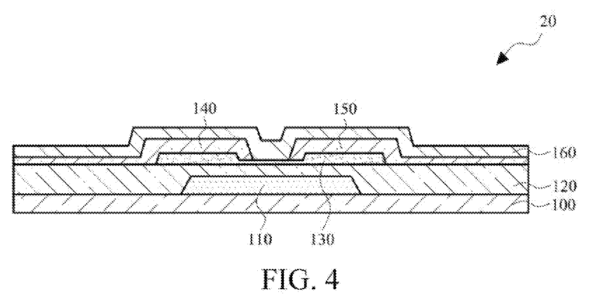

FIG. 4 is a schematic diagram of a display panel according to an embodiment of this application. Referring to FIG. 2a to FIG. 4, in an embodiment of this application, a display panel 20 obtained by using the manufacturing method according to the foregoing embodiments includes: a substrate 100 and a plurality of active switches (not shown). Each active switch includes: a gate layer 110, disposed on the substrate 100; a gate insulation layer 120, disposed on the substrate 100 and covering the gate layer 110, where a part of the gate insulation layer 120 on the gate layer 110 has a second thickness, an other part of the gate insulation layer 120 on the substrate 100 has a first thickness, and the gate insulation layer 120 has an outer surface; a semiconductor layer 130, disposed on the gate insulation layer 120; a source layer 140 and a drain layer 150, disposed on the semiconductor layer 130 and uncovering a part of the semiconductor layer 130; and a passivation layer 160, disposed on the substrate 100, where the passivation layer 160 covers the source layer 140, the drain layer 150, and the semiconductor layer 130, and the first thickness of the gate insulation layer 120 is greater than the second thickness of the gate insulation layer 120.

In an embodiment of this application, the outer surface of the gate insulation layer 120 is a flat surface. An element/film layer on the gate insulation layer 120 may be smoothly disposed on the gate insulation layer 120, to further ensure property stability of each element on the active switch.

In an embodiment of this application, the semiconductor layer 130 is a polycrystalline silicon layer, an amorphous silicon layer, or an oxide semiconductor layer.

In an embodiment of this application, the first thickness of the gate insulation layer 120 is in a range of 6000 Å to 10000 Å, and the second thickness of the gate insulation layer 120 is in a range of 500 Å to 5500 Å. The first thickness and the second thickness of the gate insulation layer 120 may be regulated according to different types and requirements of the display panel. Specifically, the first thickness of the gate insulation layer 120 may be, for example, in a range of 6000 Å to 7000 Å (and is preferably 6000 Å or 6500 Å), or in a range of 6500 Å to 7200 Å (and is preferably 6800 Å). Correspondingly, the second thickness of the gate insulation layer 120 may be, for example, in a range of 3800 Å to 4200 Å (and is preferably 4000 Å), or in a range of 3500 Å to 4500 Å (and is preferably 4000 Å).

Referring to FIG. 2a to FIG. 4, in an embodiment of this application, a display panel is provided. Compared with the display panel 20, this display panel includes: a first gate insulation layer and a second gate insulation layer superposing together. A material of the first gate insulation layer is different from a material of the second gate insulation layer. The material of the first gate insulation layer may be, for example, a SiNx material, and the material of the second gate insulation layer may be, for example, a SiOx material. The first gate insulation layer may, for example, have a same height as the gate layer, and the second gate insulation layer is disposed on the gate layer and the first gate insulation layer. Then, a semiconductor layer, a source layer, and a drain layer are disposed. An insulation effect of the gate insulation layer can be strengthened by configuring the two different types of insulation materials. In addition, parasitic capacitance between the source layer, the drain layer, and the gate layer can be regulated due to different dielectric constants of the different materials.

In some embodiments, the display panel 20 of this application may be, for example, a liquid crystal display panel, but is not limited thereto. The display panel may alternatively be an OLED display panel, a W-OLED display panel, a QLED display panel, a plasma display panel, a curved surface type display panel, or a display panel of another type.

In an embodiment of this application, compared with the gate insulation layer 120 of the exemplary display panel 10, the first thickness of the gate insulation layer 120 of the display panel 20 has a larger thickness. This can increase an antistatic capability of the active switch. By using the design in which the gate insulation layer 120 has different thicknesses and the part of the gate insulation layer 120 on the gate layer 110 has the second thickness the same as or similar to the thickness of the gate insulation layer 120 of the exemplary display panel 10, properties of the active switch can also be prevented from being affected, thereby improving adaptability of the active switch.

In this application, with assistance of the photomask process, the incomplete etching process, and the like, the thickness of the gate insulation layer 120 of the active switch is selectively increased (that is, the first thickness of the gate insulation layer 120 is increased), while the thickness of the gate insulation layer 120 on the gate layer 110 remains unchanged (that is, the second thickness of the gate insulation layer 120 remains unchanged). By using such a design, the antistatic capability of the active switch can be improved without affecting properties of the active switch, and properties of the display panel is improved, thereby ensuring stability of the display panel.

The wordings such as “in some embodiments” and “in various embodiments” are repeatedly used. The wordings usually refer to different embodiments, but they may also refer to a same embodiment. The words, such as “comprise”, “have”, and “include”, are synonyms, unless other meanings are indicated in the context thereof.

The foregoing descriptions are merely preferred embodiments of this application, and are not intended to limit this application in any form. Although this application has been disclosed above through the preferred embodiments, the embodiments are not intended to limit this application. Any person skilled in the art can make some variations or modifications, which are equivalent changes, according to the foregoing disclosed technical content to obtain equivalent embodiments without departing from the scope of the technical solutions of this application. Any simple amendment, equivalent change, or modification made to the foregoing embodiments according to the technical essence of this application without departing from the content of the technical solutions of this application shall fall within the scope of the technical solutions of this application.

What is claimed is:

1. A manufacturing method for a display panel, comprising:
providing a substrate;
forming a gate layer on the substrate;
forming a gate insulation layer on the substrate and covering the gate layer by the gate insulation layer, wherein the gate insulation layer has a first thickness;
etching, by using a photomask, the gate insulation layer on the gate layer, and making the gate insulation layer on the gate layer have a second thickness, wherein the gate insulation layer has an outer surface;
forming a semiconductor layer on the gate insulation layer; and
forming a source layer and a drain layer on the semiconductor layer, and uncovering a part of the semiconductor layer, wherein
the first thickness of the gate insulation layer is greater than the second thickness of the gate insulation layer.

2. The method for manufacturing a display panel according to claim 1, wherein the first thickness of the gate insulation layer is in a range of 6000 Å to 10000 Å.

3. The method for manufacturing a display panel according to claim 2, wherein the first thickness of the gate insulation layer is 6000 Å.

4. The method for manufacturing a display panel according to claim 1, wherein the second thickness of the gate insulation layer is in a range of 500 Å to 5500 Å.

5. The method for manufacturing a display panel according to claim 4, wherein the second thickness of the gate insulation layer is 4000 Å.

6. The method for manufacturing a display panel according to claim 1, wherein the outer surface of the etched gate insulation layer is a flat surface.

7. The method for manufacturing a display panel according to claim 1, wherein the photomask is a half-tone photomask.

8. The method for manufacturing a display panel according to claim 1, wherein the photomask is a gray-tone photomask.

9. The method for manufacturing a display panel according to claim 1, further comprising:
forming a passivation layer on the substrate.

10. The method for manufacturing a display panel according to claim 9, wherein the passivation layer covers the source layer, the drain layer, and the semiconductor layer.

11. The method for manufacturing a display panel according to claim 1, wherein the semiconductor layer is a polycrystalline silicon layer, an amorphous silicon layer, or an oxide semiconductor layer.

12. A display panel, comprising:
a substrate;
a gate layer, disposed on the substrate;
a gate insulation layer, disposed on the substrate and covering the gate layer, wherein a part of the gate insulation layer on the gate layer has a second thickness, an other part of the gate insulation layer locating on the substrate has a first thickness, and the gate insulation layer has an outer surface;
a semiconductor layer, disposed on the gate insulation layer;
a source layer and a drain layer, disposed on the semiconductor layer and uncovering a part of the semiconductor layer; and
a passivation layer, disposed on the substrate, wherein the passivation layer covers the source layer, the drain layer, and the semiconductor layer, wherein
the first thickness of the gate insulation layer is greater than the second thickness of the gate insulation layer, and the outer surface of the gate insulation layer is a flat surface.

13. The display panel according to claim 12, wherein the first thickness of the gate insulation layer is in a range of 6000 Å to 10000 Å.

14. The display panel according to claim 13, wherein the first thickness of the gate insulation layer is 6000 Å.

15. The display panel according to claim 12, wherein the second thickness of the gate insulation layer is in a range of 500 Å to 5500 Å.

16. The display panel according to claim 15, wherein the second thickness of the gate insulation layer is 4000 Å.

17. The display panel according to claim 12, wherein the gate insulation layer is a single-layer gate insulation layer.

18. The display panel according to claim 12, wherein the gate insulation layer comprises a first gate insulation layer and a second gate insulation layer superposing together.

19. The display panel according to claim 18, wherein the first gate insulation layer and the gate layer have same heights, and the second gate insulation layer is disposed on the gate layer and the first gate insulation layer.

20. A manufacturing method for a display panel, comprising:
providing a substrate;
forming a gate layer on the substrate;
forming a gate insulation layer on the substrate and covering the gate layer by the gate insulation layer, wherein the gate insulation layer has a first thickness;
etching, by using a photomask, the gate insulation layer on the gate layer, and making the gate insulation layer on the gate layer have a second thickness, wherein the gate insulation layer has an outer surface;
forming a semiconductor layer on the gate insulation layer;
forming a source layer and a drain layer on the semiconductor layer, and uncovering a part of the semiconductor layer; and
forming a passivation layer on the substrate, wherein the passivation layer covers the source layer, the drain layer, and the semiconductor layer, wherein
the photomask is a half-tone photomask or a gray-tone photomask, and the semiconductor layer is a polycrystalline silicon layer, an amorphous silicon layer, or an oxide semiconductor layer.
